(19) United States
(12) Patent Application Publication
(10) Pub. No.: US 2008/0057701 A1
(43) Pub. Date: Mar. 6, 2008

(54) METHOD FOR PREVENTION OF RESIST POISONING IN INTEGRATED CIRCUIT FABRICATION

(75) Inventors: Edward Raymond Engbrecht, Garland, TX (US); William W. Dostalik, Plano, TX (US); Ping Jiang, Plano, TX (US); Edmund Burke, Dallas, TX (US); Laura M. Matz, Murphy, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/469,598

(22) Filed: Sep. 1, 2006

(51) Int. Cl. H01L 21/4763

(52) U.S. Cl. 438/624

(57) ABSTRACT

A method of manufacturing an integrated circuit comprising fabricating a dual damascene interconnect. Fabricating the interconnect including forming a via opening in a surface of an inter-layer dielectric (ILD) located over a semiconductor substrate. Fabricating the interconnect also includes depositing a sacrificial fill material over the surface and in the via opening. Fabricating the interconnect further includes removing the sacrificial fill material from the surface, depositing a poison-blocking-layer over the surface and forming a trench pattern in a photoresist layer formed over the poison-blocking-layer. The poison-blocking-layer is configured to prevent poisons from entering the photoresist layer.

### TECHNICAL FIELD

The invention is directed, in general, to integrated circuits and their method of manufacture, and more specifically, to the fabrication of dual damascene interconnect structures.

### BACKGROUND

The drive to manufacture semiconductor devices has lead to the use of photolithography at increasingly shorter wavelengths of light to define ever-smaller feature dimensions. This, in turn, has lead to the development of photoresist materials that that are appropriately sensitive to light in the ultraviolet range. Such photoresist materials allow the definition of device features having sub-100 nanometer critical dimensions.

To define such small features, the response of the photoresist material to light must be highly uniform and predictable. Unfortunately, the photosensitivity of a photoresist can be altered if the photoresist is contaminated with photoresist poisons. E.g., the presence of poisons in certain ultraviolet photoresists can substantially reduce the resist's sensitivity to light, thereby reducing the reproducible patterning of the resist.

Accordingly, what is needed in the art is a method for manufacturing integrated circuits, and integrated circuits formed therefrom, that avoids the above-discussed disadvantages associated with poison contamination of photoresists used the circuit's fabrication.

### SUMMARY

The invention provides a method of manufacturing an integrated circuit. The method comprises fabricating a dual damascene interconnect. Fabricating the dual damascene interconnect includes forming a via opening in a surface of an inter-layer dielectric (ILD) located over a semiconductor substrate. A sacrificial fill material is deposited over the surface and in the via opening. The sacrificial fill material is removed from the surface and a poison-blocking-layer is deposited over the surface. A trench pattern is formed in a photoresist layer formed over the poison-blocking-layer. The poison-blocking-layer is configured to prevent poisons from entering the photoresist layer.

Another embodiment is an integrated circuit. The integrated circuit comprises semiconductor devices on or in a semiconductor substrate, contacts in a pre-metal dielectric layer located on the semiconductor substrate, the contacts coupled to the semiconductor devices. The integrated circuit also comprises a dual damascene interconnect located in an ILD located over the semiconductor substrate, the dual damascene interconnect coupled to at least one of the contacts. In some embodiments of the integrated circuit the dual damascene interconnect is formed by the above-described process. In some embodiments of the integrated circuit, a non-conducting poison-blocking-layer is located on a surface of the ILD.

### DRAWINGS

FIGS. 1 to 9 illustrate cross-section views of selected steps in an example method of manufacturing an integrated circuit of the invention; and

FIG. 10 shows a cross-sectional view of an example integrated circuit of the invention.

### DESCRIPTION

The present invention benefits from the discovery that a poison-blocking-layer can be placed underneath a photoresist layer being used to fabricate a dual damascene interconnect structure. The term poison-blocking-layer as used herein refers to a layer that blocks the entry of base-containing molecules that can deteriorate (“poisons”) the photosensitivity of a photoresist. Example base-containing molecules include ammonia, ethylamine, and dimethylamine borane. E.g., in many cases, the poison-blocking-layer is an amine-blocking-layer.

The poison-blocking-layer prevents the diffusion of poisons (e.g., amines) from underlying structures of the integrated circuit (IC) into the photoresist. In some cases, the poison-blocking-layer is removed from the IC at some stage in the manufacturing process after patterning the photoresist. In other cases, the poison-blocking-layer is retained in the final IC structure. Sometimes the poison-blocking-layer can serve additional functions, e.g., as a bottom anti-reflective coating (BARC), a hard mask (HM) or a chemical mechanical polishing (CMP) stop layer.

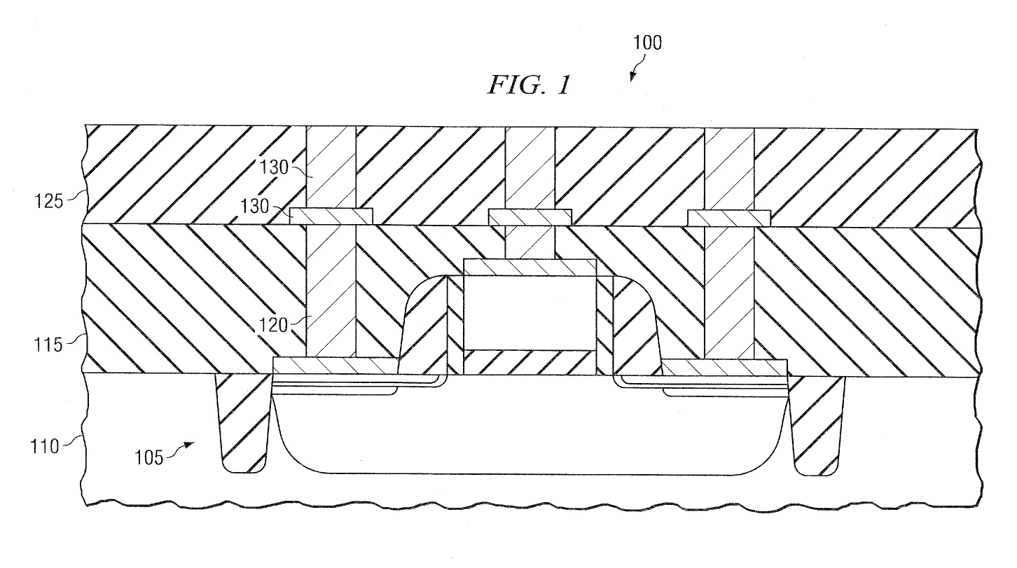

FIGS. 1-9 show cross-sectional views of an example method of manufacturing an IC 100. As shown in FIG. 1, the IC 100 comprises conventionally formed semiconductor devices 105 (e.g., nMOS and pMOS transistors and capacitors) in a semiconductor substrate 110 (e.g., a silicon wafer), a pre-metal dielectric layer 115 (e.g., phosphosilicate glass), contacts 120 coupled to the devices 105 (e.g., tungsten metal contacts). The IC 100 further includes one or more conventionally formed ILD layers 125, 212 (e.g., silicon oxide, fluorosilicate glass (FSG), or other lower dielectric constant materials) which can have metal interconnects 130 (e.g., copper vias, trenches, or lines) therein.

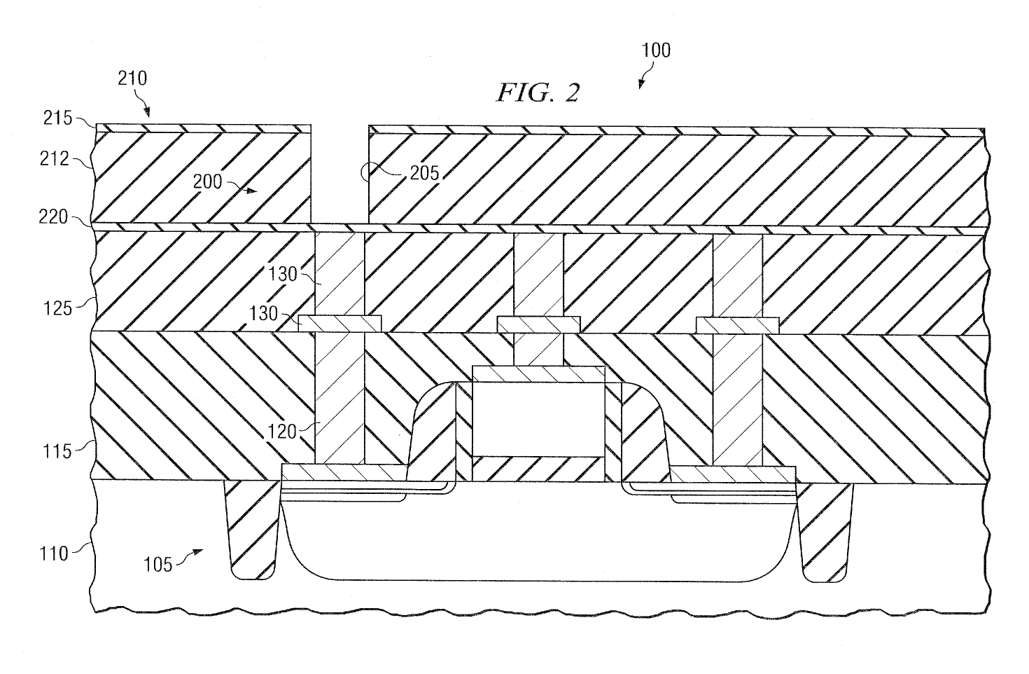

FIGS. 2-8 show selected steps in an example fabrication of a dual damascene interconnect 200. A via opening 205 of the dual damascene interconnect 200 is formed in a surface 210 of one of the ILD layers 212 located over the semiconductor substrate 110, and preferably on one of the underlying interconnects 130. The via opening 205 can be formed by any conventional photolithographic patterning and etching processes well known to those skilled in the art. As further illustrated in FIG. 2, the dual damascene interconnect 200 is formed directly above one or more of the metal interconnects 130. In other cases, e.g., if the dual damascene interconnect 200 is formed in the first ILD layer 125, then the dual damascene interconnect 200 is formed directly above one or more of the contacts 120.

To limit excessive etching of the target ILD layer 212, or to limit the damage to the ILD 212 during a resist patterning rework, it is desirable to deposit a HM 215 on the surface 210. As an example, the HM 215 can comprise silicon carbide deposited by plasma-enhanced chemical vapor deposition (PECVD), or other materials and procedures well know to those skilled in the art. Because the HM 215 does not cover the via opening 205, however, it does not block the diffusion of poisons into a subsequently deposited photoresist layer.

To limit the etching of the target ILD layer 212 to just that needed to form the via opening 205, it is also desirable to deposit an etch stop layer 220 on the underlying ILD layer 125 and metal interconnect 130. The etch stop layer 220 is deposited using conventional procedures such as PECVD or other procedures well know to those skilled in the art. Some preferred etch stop materials comprise silicon carbide (SiC), silicon nitride (SiN), silicon carbon nitride (SiCN), silicon oxycarbon (SiCO), or combined layers thereof.

In some cases, to adhere the etch stop layer 220 to the metal (e.g., copper) interconnect 130, the surface 210 is pretreated with an ammonium-containing plasma. It is believed that such ammonium plasma pretreatments can provide a source of poisons (e.g., amines) that can contaminate a subsequently deposited photoresist layer.

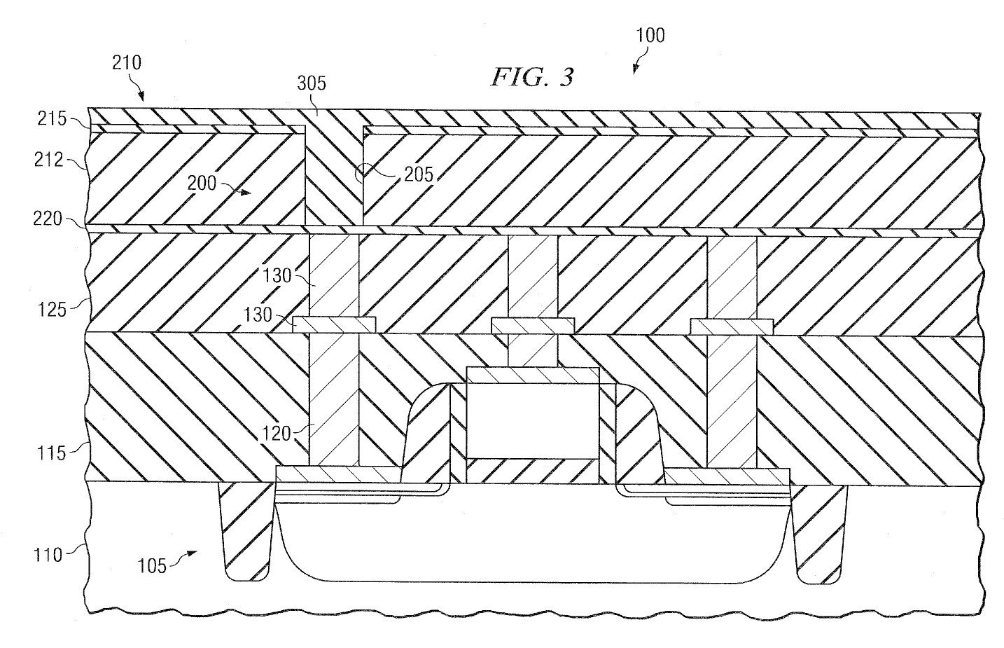

FIG. 3 shows the dual damascene interconnect 200 after depositing a sacrificial fill material 305 over the surface 210 and in the via opening 205. As shown in FIG. 3, the sacrificial fill material 305 can also get deposited on the HM 215. The sacrificial fill material 305 can be deposited using conventional processes such as CVD or spin-on-dielectrics (SOD). The sacrificial fill material 305 acts as a filler material to prevent later-deposited materials, e.g., photoresist, from entering the via opening 205. This beneficially the planarity of the surface 210 thereby improving the uniform deposition of resist. It is advantageous for the sacrificial fill material 305 to be easily removed during the etch of the ILD layer 212 to form the dual damascene interconnect 200, or by conventional ash processes. E.g., it is desirable for the sacrificial fill material 305 to be removed at about the same rate as the ILD layer 212 under the etch conditions used to form a trench of the dual damascene interconnect 200.

Some preferred sacrificial fill material 305 comprise a BARC. As well known to those skilled in the art, a BARC layer helps to eliminate photolithographic artifacts and thereby improve the uniformity of feature definitions across the substrate 110. However, in the present case, a BARC serving as the sacrificial fill material 305 is used for its structural role of filling the via opening 205 and its etch selectivity (being similar to the ILD layer 212), rather than its optical properties. Examples of suitable sacrificial fill material 305 include an organic BARC material (e.g., a 193 nm anti-reflective coating such as ACR29A from Brewer Science, Inc., Rolla Mo.). In other cases, however, the sacrificial fill material 305 can comprise an inorganic material such a silicon oxide based BARC materials, such as DUO™ (Honeywell Electronic Materials, Tempe Ariz.).

It is believed that such sacrificial fill materials 305, however, do not prevent poisons from diffusing through the filled via opening 205 and into a subsequently deposited photoresist layer.

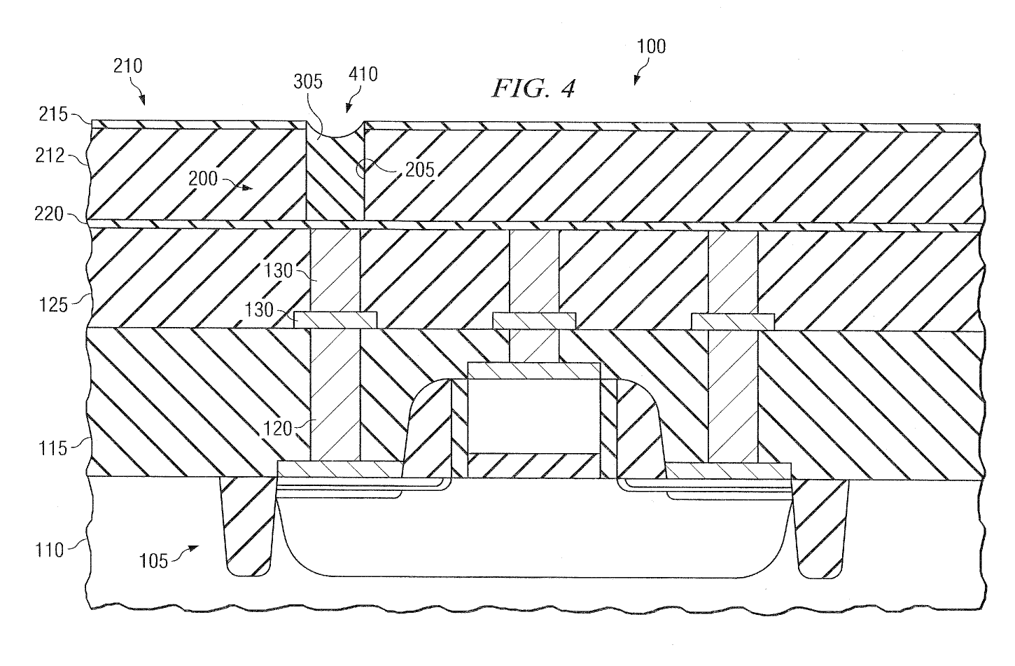

FIG. 4 shows the dual damascene interconnect 200 after removing the sacrificial fill material 305 from the surface 210. The sacrificial fill material 305 is removed in a manner that makes the surface 210 highly planar, so that subsequently deposited layers, such as a second BARC layer, or a photoresist layer, will have a uniform thickness over the entire substrate 110. This, in turn, improves the uniform definition of features across the substrate 110. Desirable methods of removing the sacrificial fill material 305 include an etch-back process comprising e.g., oxygen-containing plasma ash. Preferably the sacrificial fill material 305 is not removed from the via opening 205 so that the surface 210 is planar. However, in some cases, a portion of the sacrificial fill material 305 gets removed from the via opening 205 to form a recess 410.

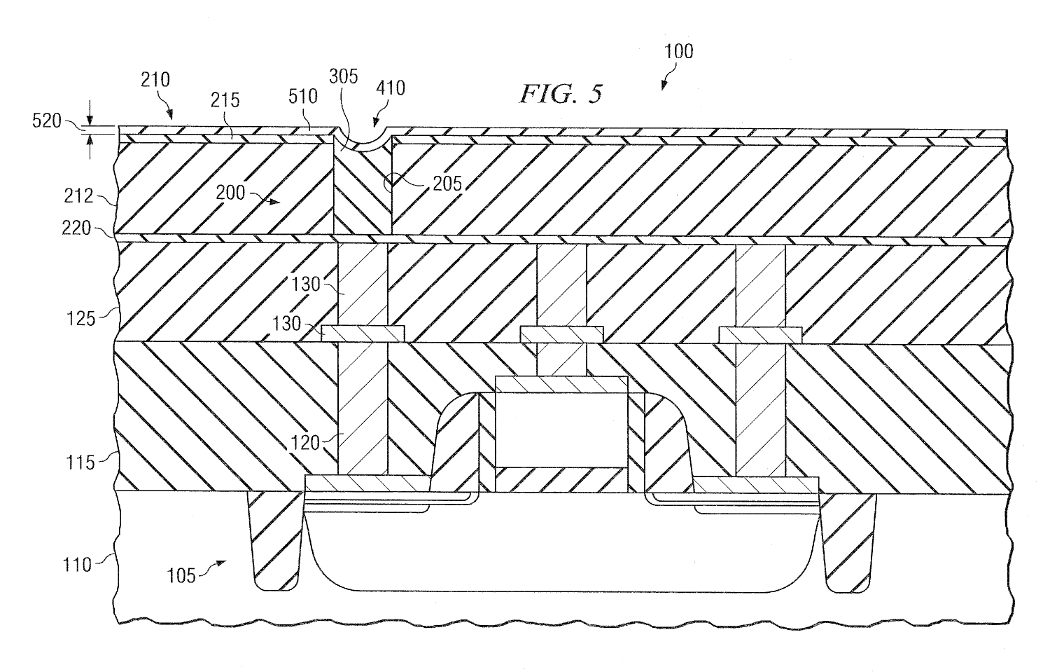

FIG. 5 shows the dual damascene interconnect 200 after depositing a poison-blocking-layer 510 over the surface 210. E.g., as shown in FIG. 5 the poison-blocking-layer 510 is deposited on the HM 215. The poison-blocking-layer 510 can be deposited using conventional technical such as chemical vapor deposition (CVD), physical vapor deposition (PVD), or atomic layer deposition (ALD). In situations where there is a recess 410, depositing the poison-blocking-layer 510 further includes at least partially filling the recess 410 with the poison-blocking-layer 510. The poison-blocking-layer 510 does not fill the entire via opening 205 in cases where the sacrificial fill material 305 is in the via opening 205.

It is important for the poison-blocking-layer 510 to not line the entire via opening 205 because the poison-blocking-layer 510 will then become part of the dual damascene interconnect 200. If the dielectric constant of the poison-blocking layer is higher than the dielectric constant of the ILD, then it is less desirable for the poison-blocking-layer 510 to be retained as part of a liner in the dual damascene interconnect 200. Such may be the case when e.g., the poison-blocking-layer 510 is composed of a high dielectric constant material (e.g., a dielectric constant greater than 4). The presence of such a high dielectric constant material in the ILD 125 can disadvantageously increase the effective dielectric constant of the ILD 125 and thereby increase the RC-delay time of the IC 100.

The selection of suitable materials, deposition conditions, and the thickness of the poison-blocking-layer 510 have not been previously recognized as result-effective-variables that are important to the fabrication of dual damascene interconnects.

In some cases the poison-blocking-layer 510 comprises a dense material (e.g., a density of about 2 gm/cm³ or greater) that can impede the diffusion of poisons through it. Examples include metal nitrides like titanium silicon nitride or tantalum nitride, or metals like titanium or tantalum. Such conducting materials, however, must be removed from the completed IC 100 because they would otherwise create electrical shorts in the IC 100.

In addition, some materials, such as tantalum, can present challenges when etching to from the trench of the dual damascene interconnect 200. E.g., aggressive etch conditions must be used to remove the tantalum poison-blocking-layer 510 before switching to milder conditions used to etch the ILD 125. In such instances, there is a risk of over-etching the ILD 125.

In other cases, the poison-blocking-layer 510 comprises a non-conducting material. The use of a non-conducting material has an advantage compared to a conducting poison-blocking-layer 510 in that it can be left on the surface 210 in the final IC 100. This eliminates the need to perform additional processing steps (e.g. CMP) to remove the poison-blocking-layer 510. Example non-conducting materials for the poison-blocking-layer 510 include silicon carbide (SiC) or boron-carbonitride (BCₓN_{y}).

In some cases, however, it is still desirable to remove the non-conducting poison-blocking-layer 510 from the completed IC 100. An important benefit of removing the poison-blocking 510 is that it cannot affect the effective dielectric constant of the ILD 125.

Some preferred non-conducting materials for the poison-blocking-layer 510 include metal oxides such as aluminum oxide (Al₂O₃) or tantalum oxide (Ta₂O₅). Metal oxides having a high density are preferred, e.g., the density of Al₂O₃ and Ta₂O₅ are about 4 and 8 gm/cm³, respectively.

In some cases, it is beneficial to choose a poison-blocking-layer 510 that can be deposited as a thin layer and yet still prevent diffusion of poisons through it. E.g., sometimes the thickness 520 of a SiC poison-blocking-layer 510 required to prevent the diffusion of poisons (e.g. more than about 40 nm) is greater than desired in the case where the poison-blocking-layer 510 is retained in the completed IC 100. E.g., a 40 nm thick poison-blocking-layer 510 made of a material with a high dielectric constant (e.g., a silicon nitride having a dielectric constant of about 7) could significantly contribute to an increase in the effective dielectric constant of the ILD layer 125.

The use of a dense non-conducting metal oxide, such as Al₂O₃ is preferred because this permits a thinner poison-blocking-layer 510 to be used (e.g., a thickness 520 of about 50 nm, more preferably 20 nm or less, and more preferably 5 to 2.5 nm). It is desirable to use a thin poison-blocking-layer 510 because a thin poison-blocker-layer will have less effect on the effective dielectric constant of the ILD layer 125 as compared to a thicker layer.

In some cases, material used to form the poison-blocking-layer 510 is selected because it can be deposited at low temperatures. E.g., the temperatures (e.g., 350 to 400° C.) at which Al₂O₃, SiC or BCₓN_{y} containing poison-blocking-layers 510 are deposited may be incompatible with certain sacrificial fill materials 305. E.g., organic sacrificial fill materials 305, comprising organic polymers such as ACCUFLO® (Honeywell Electronic Materials, Tempe Ariz.) become unstable at temperatures above 250° C.

Certain non-conducting metal oxides, such as Al₂O₃, desirable because they can be deposited at temperatures that are compatible with certain types of sacrificial fill materials 305 (e.g., about 200 to 250° C.). E.g., in some preferred embodiments depositing the poison-blocking-layer 510 comprises using an atomic-layer deposition (ALD) process, at less than 250° C., to deposit an Al₂O₃ layer to a thickness 520 of about 5 nm. However, CVD or PVD methods at these temperatures could also be used to deposit the Al₂O₃ layer, or other metal oxide layer, to form the poison-blocking-layers 510.

In some cases, the material of the poison-blocking-layer 510 can be selected for its ability to perform other functions that facilitate the manufacture of the IC 100. For instance, in some embodiments, the poison-blocking-layer 510 serves as a HM for the ILD layer 212. E.g., an Al₂O₃ poison-blocking-layer 510 can also functions as a HM, thus eliminating the need to deposit a separate HM layer 215.

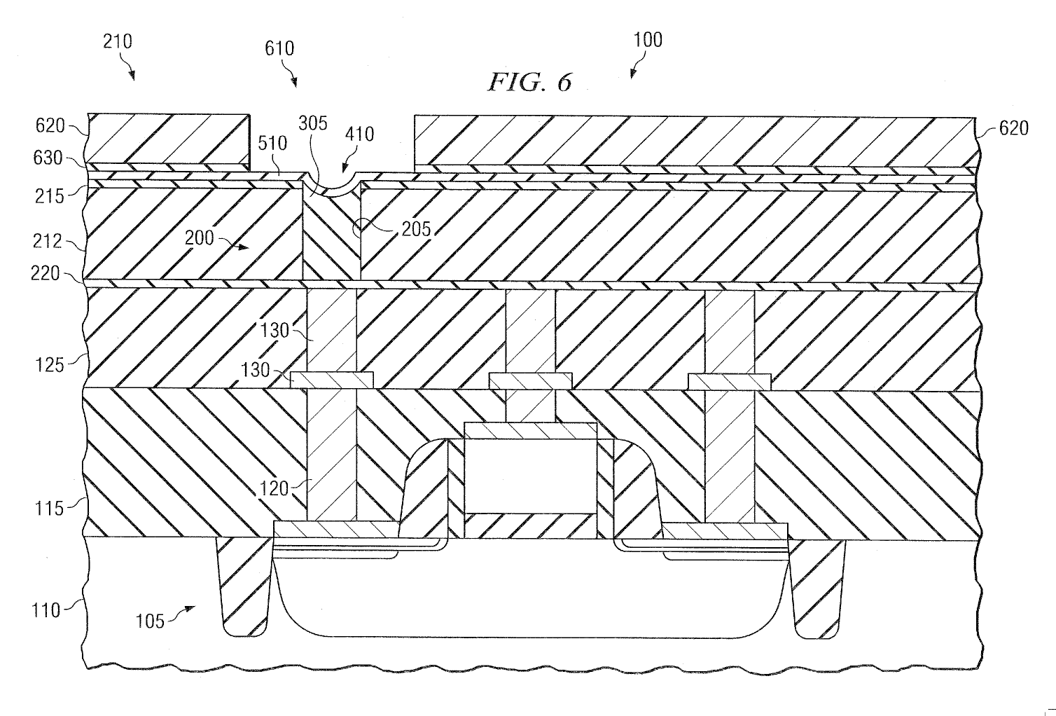

FIG. 6 shows the dual damascene interconnect 200 after forming a trench pattern 610 in a photoresist layer 620 formed over the poison-blocking-layer 510. As discussed above, the poison-blocking-layer 510 that the photoresist layer 620 is formed over is configured to prevent poisons from entering the photoresist layer 620.

Preferably, the photoresist is an ultraviolet photoresist, and more preferably a 193 nm resist. As well known to those skilled in the art, there are discrete ultraviolet exposure technologies corresponding to particular wavelengths of light emitted by e.g., lasers. For instance, conventional lasers used in photolithography typically emit ultraviolet light at wavelengths of 248 nm, 193 nm, or 157 nm. Photoresists that are exposed to these wavelengths of light are termed 248 nm resists, 193 nm resists and 157 nm resists, respectively. The photoresist, however, could be any type of resist material whose photosensitivity, on exposure to ultraviolet light or other wavelengths of radiation, is affected by the presence of poisons.

In some embodiments a BARC layer 630 is deposited (e.g., via a spin-on process) on the poison-blocking-layer 510 before depositing the photoresist layer 620. The BARC can comprise any organic or inorganic material capable of reducing light reflectance during photolithography to define the trench pattern 610. In some cases the BARC comprises the same material as the sacrificial fill material 305. In other embodiments however, the poison-blocking-layer 510 can serve as the BARC for trench patterning. E.g., an Al₂O₃ poison-blocking-layer 510 can also function as the BARC, thus eliminating the need to deposit a separate BARC layer 630.

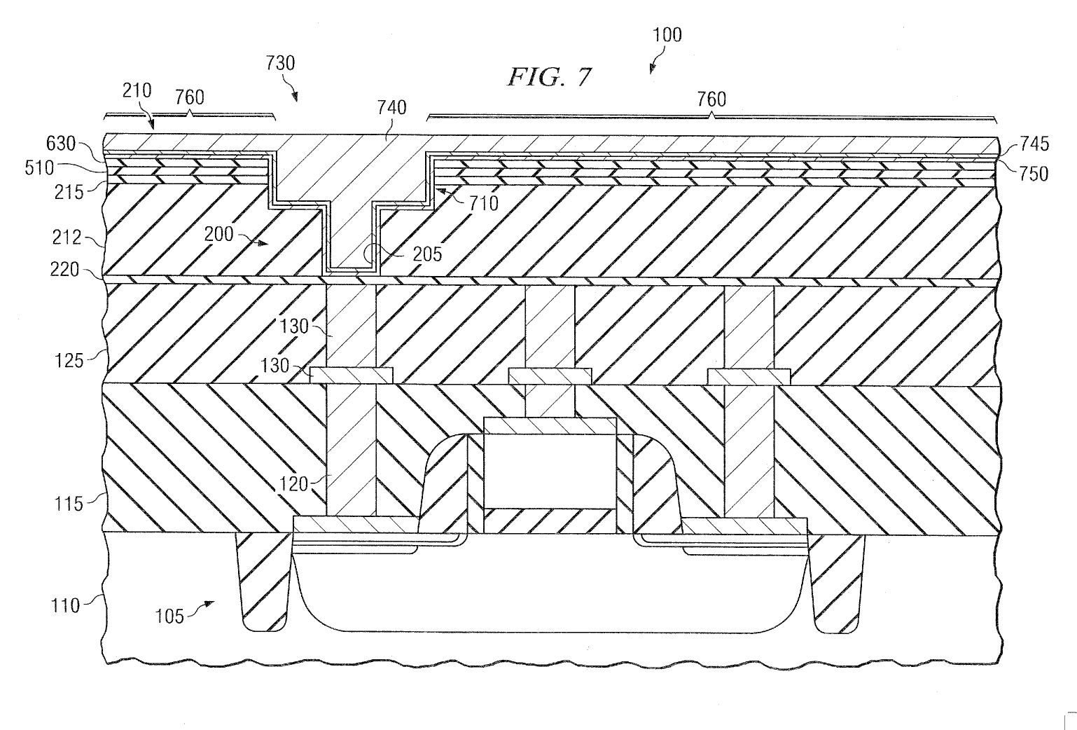

FIG. 7 shows the dual damascene interconnect 200 after forming a trench opening 710 in the ILD 125 and depositing a metal in the via 205 and trench 710 openings. The photoresist 620 (FIG. 6) is removed after forming the trench using e.g., conventional ash processes. Forming the trench opening 710 can comprise the same conventional etching procedures used to form the via opening 205. Typically a timed etch is used. In some cases, it is desirable to use etching chemistries to specifically remove the portions of the poison-blocking-layer 510 that were exposed by the trench pattern 610, and then adjust the etching chemistry to remove the desired amount of ILD 125 to form the trench opening 710.

Consider as an example the case where the ILD 125 comprises organo-silicate glass (OSG) and the poison-blocking-layer 510 comprises tantalum. A suitable etch process for removing the poison-blocking-layer 510 comprises a conventional plasma etch for etching metals using e.g., Cl-based plasma chemistry. For poison-blocking-layers 510 having a thickness 520 of less than about 50 nm, it is more desirable to use a plasma etch relying on ion bombardment and using inert chemistry (e.g., Ar-based plasma chemistry). A suitable etch process for removing the ILD 125 (having a thickness of about 200 nm) comprises a conventional plasma etch for etching dielectrics using e.g., a CₓF_{y}-based plasma chemistry.

FIG. 7 also shows the dual damascene interconnect 200 after forming a metal structure 730 in the via 205 and trench 710 openings using materials and procedures well known to those skilled in the art. E.g., forming the metal structure 730 can comprise a CVD or PVD deposited barrier layer 740 (e.g., tantalum nitride, TaN) and seed layer 745 (e.g., Cu), and an electrochemically deposited metal layer 750 (e.g., Cu). As further illustrated in FIG. 7, as part of forming the metal structure 730 excess metal 760 gets deposited on the surface 210 outside of the trench opening 710.

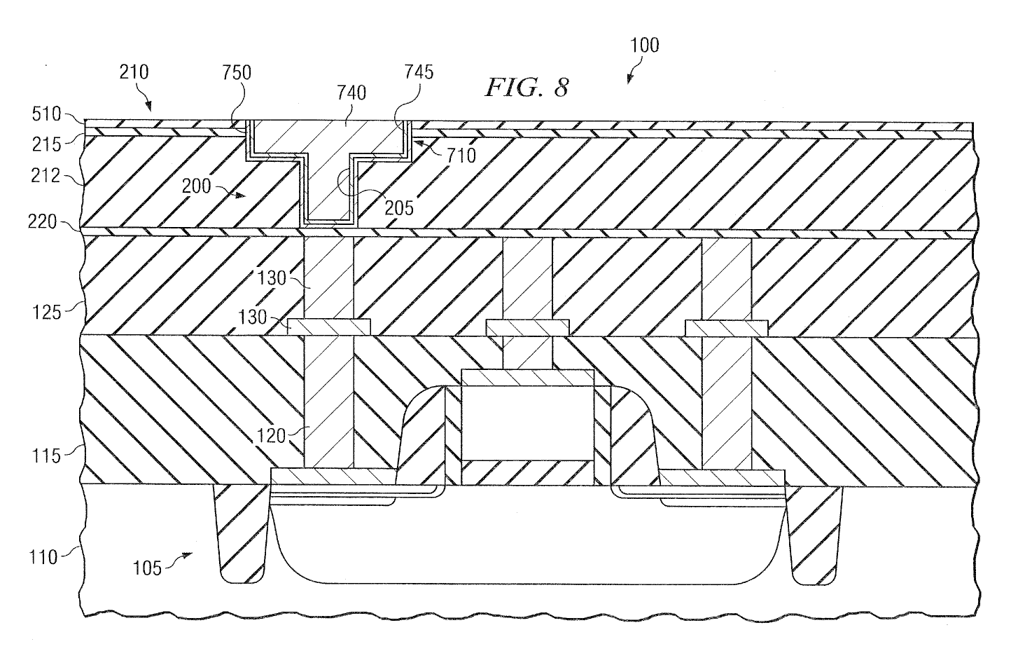

FIG. 8 shows the dual damascene interconnect 200 after removing the excess metal 760 from outside of the via and trench openings 205, 710. In preferred embodiments the excess portions 810 are removed by CMP. In some cases it is advantageous to use the poison-blocking-layer 510 as a CMP stop for removal of the metal structure 730 (FIG. 7). That is, the CMP conditions are selected such that there is a high removal rate for the metal structure 730 but low removal rate for the poison-blocking-layer 510. E.g., a poison-blocking-layer 510 of Al₂O₃ can be used as a CMP stop for the TaN barrier layer 740. However, in other cases the poison-blocking-layer 510 is removed by the CMP process, and the HM 215 is used as a CMP stop for the poison-blocking-layer 510.

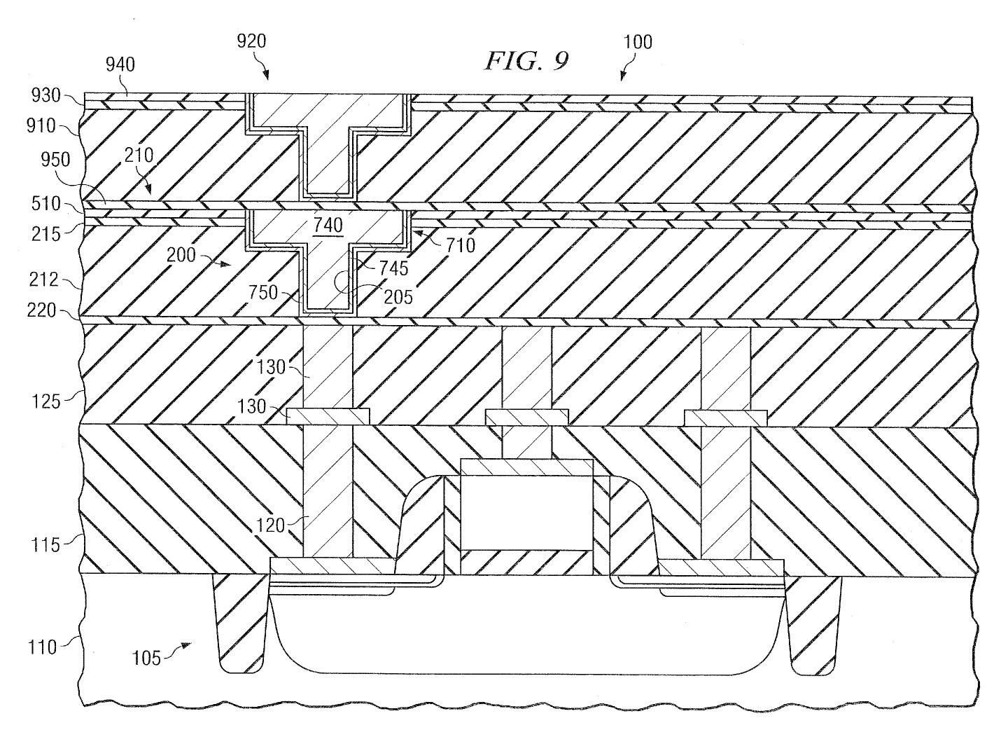

FIG. 9 shows the IC 100 after depositing one or more ILD layer 910 and forming one or more dual damascene interconnects 920 in the ILD layers 910. The dual damascene interconnect 920 can be formed in the same manner as described for the dual damascene interconnect 200 in the context of FIG. 2-8, including forming a poison-blocking-layer 930, or HM 940, or both on the ILD layer 910.

There is an advantage in leaving the poison-blocking-layer 510 on the underlying ILD 212 when forming the next ILD 910. When ammonium plasma pre-treatment is performed to improve the adhesion of an etch stop layer 950 for the metal structure of the next ILD 910 (analogous to the metal structure 730 depicted in FIG. 7), the surface 210 of the underlying ILD 212 is protected from damage by the poison-blocking-layer 510. The poison-blocking-layer 930 performs similar functions for subsequently formed additional ILDs and interconnections.

FIG. 9 illustrates another aspect of the invention, an IC 100. The IC 100 comprises one or more semiconductor device 105 on or in a semiconductor substrate 110 and contacts 120 in a pre-metal dielectric layer 115 located on the semiconductor substrate 110, the contacts 120 coupled to the semiconductor devices 105. The IC 100 also comprises a dual damascene interconnect 200 that is located in an ILD 212 located over the semiconductor substrate 110, and that is coupled to at least one of the contacts 120.

The dual damascene interconnect 200 can be formed by any of the embodiments of the process described above in the context of FIG. 2-8. For instance, the dual damascene interconnect 200 can be formed by forming a via opening 205 in a surface 210 of the ILD 212, covering the surface 210 and filling the via opening 205 with a sacrificial fill material 305 (FIG. 3), and removing the sacrificial fill material 305 from the surface 210. The process to form the dual damascene interconnect 200 further includes depositing a poison-blocking-layer 510 over the surface 210, forming a trench pattern 610 in a photoresist layer 620 (FIG. 6) formed over the poison-blocking-layer 510, forming a trench opening 710 in the surface 210 and over the via opening 205, and filling the via and trench openings 205, 710 with a metal structure 730.

In some cases the poison-blocking-layer is retained e.g., as part of a CMP stop for removing one or more metal layer 740, 745, 750 (FIG. 7) from the surface 210 after filling the via and trench openings 205, 710 with the metal structure 730. In such cases a non-conducting poison-blocking-layer 510 is retained on the surface of the ILD 212. As discussed above, preferred embodiments of the non-conducting poison-blocking-layer 510 comprise metal oxides, such as aluminum oxide, and have a thickness 520 of about 50 nm or less and in some cases about 25 nm or less, and a density of at least about 2 gm/cm³, and in some cases, 4 gm/cm³ or greater.

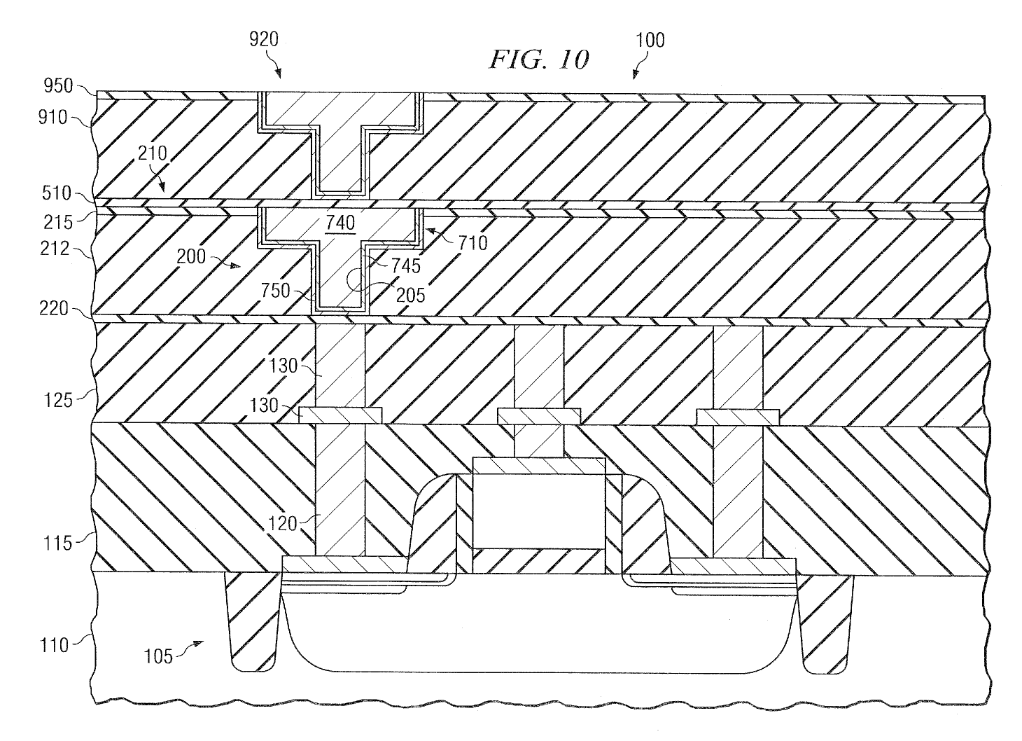

In other cases, such as illustrated in FIG. 10, the poison-blocking-layer 510 (FIG. 9) is removed, e.g., as part of a CMP process to removing one or more metal layer 740, 745, 750 (FIG. 7) from the surface 210 after filling the via and trench openings 205, 710 with the metal structure 730. The advantage of such embodiments is that a larger scope of materials can be used as the poison-blocking-layer 510. E.g., the poison-blocking-layer 510 can comprise a conductive material.

Those skilled in the art to which the invention relates will appreciate that other and further additions, deletions, substitutions and modifications may be made to the described example embodiments, without departing from the invention.

1. A method of manufacturing an integrated circuit, comprising:
fabricating a dual damascene interconnect, including:
forming a via opening in a surface of an inter-layer dielectric (ILD) located over a semiconductor substrate;
depositing a sacrificial fill material over said surface and in said via opening;
removing said sacrificial fill material from said surface;
depositing a poison-blocking-layer over said surface; and
forming a trench pattern in a photoresist layer formed over said poison-blocking-layer, wherein said poison-blocking-layer is configured to prevent poisons from entering said photoresist layer.

2. The method of claim 1, wherein removing further includes removing a portion of said sacrificial fill material from said via opening to form a recess.

3. The method of claim 1, wherein said poison-blocking-layer comprises a non-conducting material.

4. The method of claim 1, wherein said poison-blocking-layer has a thickness of about 50 nm or less.

5. The method of claim 1, wherein said poison-blocking-layer has a density of at least about 2 gm/cm³.

6. The method of claim 1, wherein said poison-blocking comprises aluminum oxide.

7. The method of claim 1, wherein depositing said poison-blocking comprises one of an ALD, CVD or PVD process.

8. The method of claim 1, further including depositing a bottom antireflective coating (BARC) on said poison-blocking-layer before depositing said photoresist layer.

9. The method of claim 1, wherein said poison-blocking-layer serves as a bottom antireflective coating when forming said trench pattern.

10. The method of claim 1, further including forming a trench opening in said ILD and forming a metal structure in said via and trench openings.

11. The method of claim 10, further includes using said poison-blocking-layer as a CMP stop layer for removing excess portions of said metal structure from outside of said via and trench openings.

12. The method of claim 10, further including removing said poison-blocking-layer before filling said via and trench openings with said metal structure.

13. An integrated circuit (IC), comprising:
semiconductor devices on or in a semiconductor substrate;
contacts in a pre-metal dielectric layer located on said semiconductor substrate, said contacts coupled to said semiconductor devices;
a dual damascene interconnect located in an inter-layer dielectric (ILD) located over said semiconductor substrate, said dual damascene interconnect coupled to at least one of said contacts, and formed by a process including:
forming a via opening in a surface of said ILD;
covering said surface and filling said via opening with a sacrificial fill material;
removing said sacrificial fill material from said surface;
depositing a poison-blocking-layer over said surface;
forming a trench pattern in a photoresist layer formed over said poison-blocking-layer, wherein said poison-blocking-layer is configured to prevent poisons from entering said photoresist layer;
forming a trench opening in said surface and over said via opening; and
filling said via and trench openings with a metal structure.

14. The IC of claim 13, wherein said poison-blocking-layer comprises a conductive material.

15. The IC of claim 13, wherein said poison-blocking-layer retained as part of a CMP stop for removing one or more metal layer from said surface after filling said via and trench openings with said metal structure.

16. The IC of claim 13, wherein said poison-blocking-layer is removed as part of a CMP process to remove one or more metal layer from said surface after filling said via and trench openings with said metal structure.

17. An integrated circuit, comprising:
semiconductor devices on or in a semiconductor substrate;
contacts in a pre-metal dielectric layer located on said semiconductor substrate, said contacts coupled to said semiconductor devices;
a dual damascene interconnect located in an inter-layer dielectric (ILD) located over said semiconductor substrate, said dual damascene interconnect coupled to at least one of said contacts; and
a non-conducting poison-blocking-layer on a surface of said ILD.

18. The circuit of claim 17, wherein said non-conducting poison-blocking-layer comprises a metal oxide.

19. The circuit of claim 17, wherein said non-conducting poison-blocking-layer comprises aluminum oxide.

20. The circuit of claim 17, wherein said non-conducting poison-blocking-layer has a thickness of about 50 nm or less and a density of at least about 2 gm/cm³.
